(19) United States
(12) Patent Application Publication
(10) Pub. No.: US 2019/0199336 A1
(43) Pub. Date: Jun. 27, 2019

(54) COMPARATOR HAVING DIFFERENTIAL FDSOI TRANSISTOR PAIR WITH GATE CONNECTED TO BACK-GATE TO REDUCE RTS NOISE

(71) Applicant: GLOBALFOUNDRIES INC., Grand Cayman (KY)

(72) Inventors: Vijay Kanagala, San Ramon, CA (US); Don R. Blackwell, Santa Clara, CA (US)

(21) Appl. No.: 15/850,702

(22) Filed: Dec. 21, 2017

(51) Int. Cl. H03K 5/24; H01L 27/12; H03K 17/16

(52) U.S. Cl. CPC H03K 5/2481; H03K 17/161; H01L 27/1203

(57) ABSTRACT

Embodiments of the present disclosure provide a circuit structure including: a first transistor having a gate, a drain connected to a first node, a FDSOI channel region positioned between a source and the drain, a back-gate, separated from the FDSOI channel with a buried insulator layer positioned beneath the FDSOI channel, wherein the back-gate of the first transistor and a first input signal voltage are connected to the gate of the first transistor, and the source is connected to a first shared node; and a second transistor having a gate, a source connected to the first shared node, a drain connected to a second node, a FDSOI channel positioned between the source and drain, and a buried insulator positioned beneath the FDSOI channel and a back-gate, wherein the back-gate of the second transistor and a second input signal voltage are connected to the gate of the second transistor.

### TECHNICAL FIELD

Embodiments of the disclosure relate generally to a comparator with fully-depleted SOI differential pair transistors and adjusting the transconductance by coupling the gate terminal to a back-gate terminal, and more particularly, to circuit structures for adjusting comparator transconductance and methods of operating the same. The various embodiments described herein may be used in a variety of applications, e.g., adjusting the transconductance to affect random telegraph signal noise and power supply rejection ratio.

### BACKGROUND

In electrical hardware, a comparator is an important component for implementing digital and analog logic. Generally, a comparator includes a differential pair of transistors, a current source, and a current sink. Each transistor of the differential pair traditionally has a source terminal, a drain terminal, a gate terminal, and a body terminal. A comparator accepts two analog signal inputs, either voltage or current, and produces a binary output. The output signal provides a function of which input voltage is higher. Comparators are commonly used in devices that measure and digitize analog signals, such as analog-to-digital converters and relaxation oscillators. While comparators offer many advantages, managing input referred noise, random telegraph signal noise, power supply ratio, and/or other characteristics during operation continues to be a technical challenge.

### SUMMARY

A first aspect of the present disclosure provides a circuit structure including: a first transistor having a gate terminal, a drain terminal electrically coupled to a first node, a fully depleted semiconductor insulator (FDSOI) channel region positioned between a source terminal and the drain terminal, a back-gate terminal, separated from the FDSOI channel region with a buried insulator layer positioned beneath the FDSOI channel region, wherein the back-gate terminal of the first transistor and a first input signal voltage are electrically connected to the gate terminal of the first transistor, and the source terminal is electrically connected to a first shared node, and a second transistor having a gate terminal, a source terminal electrically connected to the first shared node, a drain terminal electrically connected to a second node, a FDSOI channel region positioned between the source and drain terminal, and a buried insulator positioned beneath the FDSOI channel region and a back-gate terminal, wherein the back-gate terminal of the second transistor and a second input signal voltage are electrically connected to the gate terminal of the second transistor, and wherein the first and second transistor acting together comprise a differential pair.

A second aspect of the present disclosure provides a circuit structure including: a differential transistor pair further including, a first transistor having a gate terminal, a drain terminal electrically coupled to a first node, a fully depleted semiconductor insulator (FDSOI) channel region positioned between a source terminal and the drain terminal, a back-gate terminal, separated from the FDSOI channel region with a buried insulator layer positioned beneath the FDSOI channel region, wherein the back-gate terminal of the first transistor and a first input signal voltage are electrically connected to the gate terminal of the first transistor, and the source terminal is electrically connected to a first shared node; a second transistor having a gate terminal, a source terminal electrically connected to the first shared node, a drain terminal electrically connected to a second node, a FDSOI channel region positioned between the source and drain terminal, and a buried insulator positioned beneath the FDSOI channel region and a back-gate terminal, wherein the back-gate terminal of the second transistor and a second input signal voltage are electrically connected to the gate terminal of the second transistor; a plurality of biasing current sink transistors electrically connected to the first shared node of the differential pair; and a plurality of load current source transistors electrically connected to the first and second node of the differential pair.

A third aspect of the present disclosure provides a method for operating a comparator, the method comprising: applying a first differential input voltage signal to a gate terminal of a first differential transistor, wherein the first differential transistor includes a drain terminal electrically connected to a first node, a fully depleted semiconductor insulator (FDSOI) channel region positioned between a source terminal and the drain terminal, and a back-gate terminal separated from the FDSOI channel region with a buried insulator layer positioned beneath the FDSOI channel region, wherein the source terminal is electrically connected to a first shared node; connecting a source of a second differential transistor to the first shared node, wherein the second differential transistor including a gate, a drain terminal electrically connected to a second node, a FDSOI channel region positioned between the source and drain terminal, and a buried insulator positioned beneath the FDSOI channel region and a back-gate terminal; applying a second differential input voltage signal to the gate terminal of the second differential transistor, wherein the first and second differential input voltage signals have a first level of Random Telegraph Signal (RTS) noise; adjusting the transconductance of the first and second differential transistor by coupling the back-gate terminals of the first and second differential transistor to the respective gate terminals of the first and second differential transistors, wherein adjusting the transconductance reduces the RTS noise to a second level.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows a schematic view of a conventional transistor structure.

FIG. 2 shows a schematic view of a conventional comparator structure.

FIG. 3 shows a cross-sectional view of a fully depleted SOI (FDSOI) transistor structure with a back-gate region beneath a buried insulator layer according to embodiments of the disclosure.

FIG. 4 shows a schematic view of a differential pair circuit structure according to embodiments of the disclosure.

FIG. 5 shows a schematic view of a comparator circuit structure according to embodiments of the disclosure.

FIG. 6 shows a representative plot of voltage (in decibels) versus Frequency (in Hertz) comparing the power supply rejection ratio of conventional comparators to the comparator circuit structure according to embodiments of the disclosure.

FIG. 7 shows an example of a process flow diagram for operating a comparator of the circuit structure according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific exemplary embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

The following description describes various embodiments of a comparator circuit design that uses fully depleted SOI (FDSOI) transistor technology. The comparator circuit structure includes a differential pair of FDSOI transistors electrically coupled to a current source and a current sink. Each differential pair of FDSOI transistors has a gate terminal, a source terminal, a drain terminal, and a back-gate terminal. The structure of an FDSOI transistor will be discussed in more detail herein. When each back-gate terminal is electrically connected to the gate terminal of the respective transistor, the transconductance of the FDSOI transistor devices increases. This coupling of the gate and back-gate terminals may allow the device to act as greater than a single transistor, for example 1 and ¼ transistor or 1 and ⅓ transistor, and thus may enable the transconductance of the transistors in the comparator to be adjusted. Random trapping and de-trapping of charge carriers at the channel interfaces is inherent in each transistor device and causes a shift in the overdrive voltage of the differential pair transistors when a tail current sink is used. When transconductance is increased, this causes a reduction in overdrive voltage shift and a reduction in input referred noise and random telegraph signal noise (RTS). In addition to coupling the gate and back-gate of the differential pair, FDSOI transistors located in the current sink and current source may also have electrically connected gate and back-gate terminals. The resulting comparator structure may reduce the need for larger circuit components, decrease input referred noise, and/or improves the power supply rejection ratio.

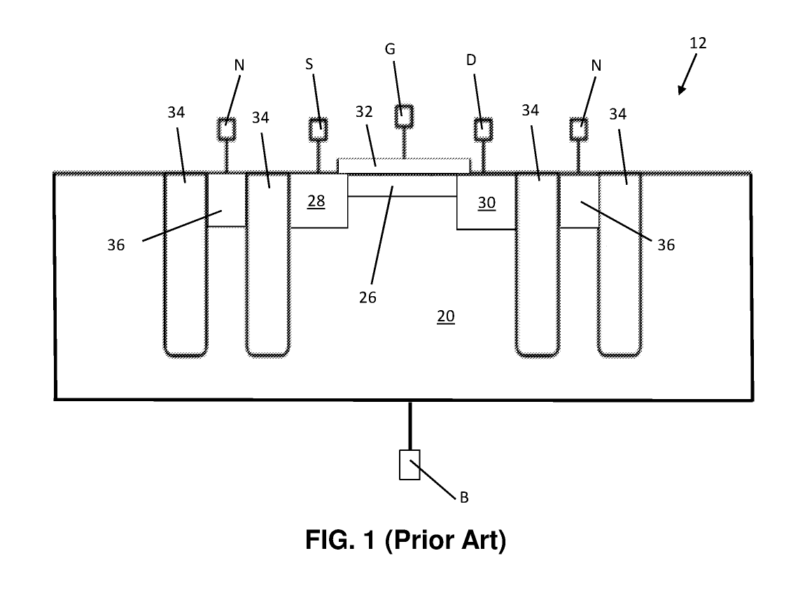

Referring to FIG. 1, a conventional transistor 12 is depicted as an example to emphasize structural and operational differences relative to embodiments of the present disclosure, and transistor elements included therein. Conventional transistor 12 may be fabricated, e.g., by way of conventional fabrication techniques, which may operate on a bulk silicon substrate. Conventional transistor 12 thus may be formed in a substrate 20 including, e.g., one or more semiconductor materials. Substrate 20 can include any currently known or later-developed semiconductor material, which may include without limitation, silicon, germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). The entirety of substrate 20 or a portion thereof may be strained.

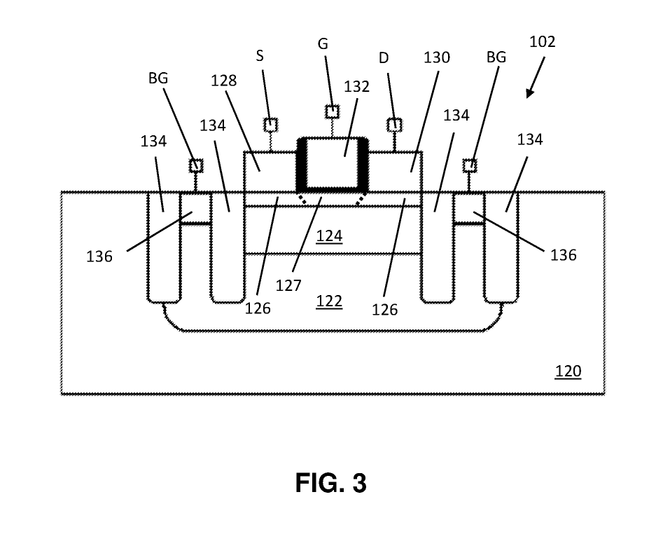

Source and drain nodes S, D of conventional transistor 12 may be coupled to regions of substrate 20 which include conductive dopants therein, e.g., a source region 28 and a drain region 30 separated by a channel region 26. A gate region 32 formed on channel region 26 can be coupled to a gate node G to control a conductive channel within channel region 26. A group of trench isolations 34 may be formed from electrically insulating materials such that regions 26, 28, 30 are laterally separated from parts of other transistors. As shown, trench isolations 34 form an insulating barrier between terminals 36 and regions 26, 28, 30 and/or other elements. An additional body terminal B or body node B, such as those found in field effect transistors, may be used to bias the transistor during operation. Further features of each element in conventional transistor 12 (e.g., function and material composition) are described in detail elsewhere herein relative to similar components in an FDSOI transistor 102 (FIG. 3) according to embodiments of the disclosure.

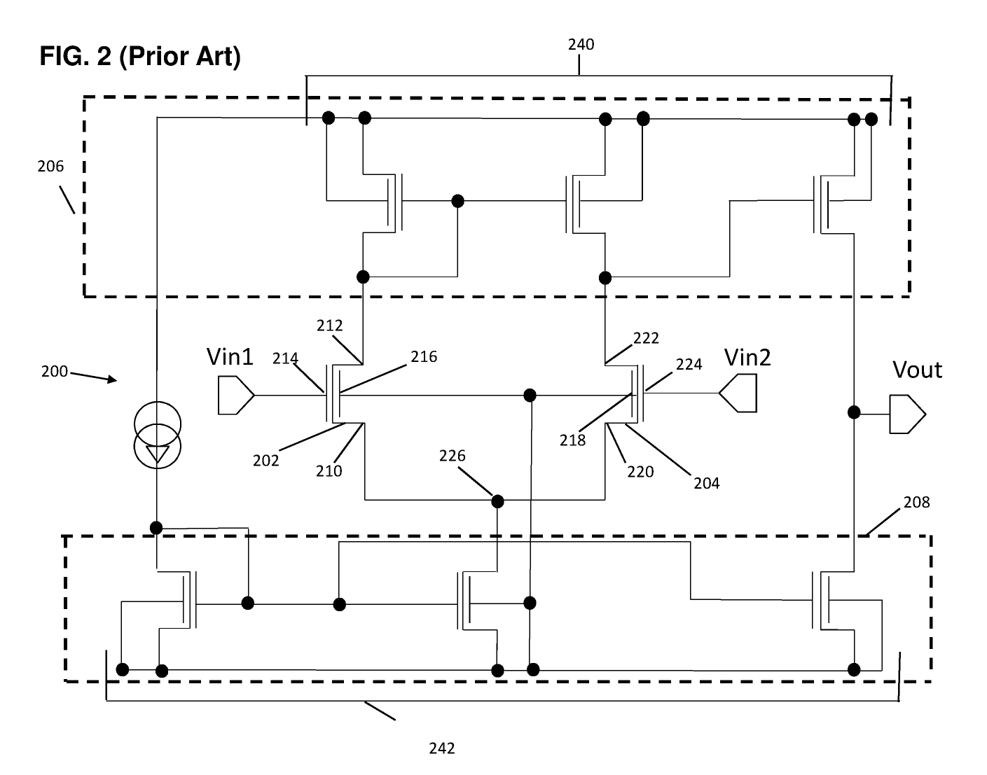

Referring to FIG. 2, a conventional comparator structure 200 is depicted as an example to emphasize structural and operational differences relative to embodiments of the present disclosure, and circuit elements included therein. Conventional comparator 200 may have a differential pair of transistors, e.g., first transistor 202 and second transistor 204. First transistor 202 and second transistor 204 of the differential pair are conventional transistors as discussed in FIG. 1. First transistor 202 may have a source terminal 210, a drain terminal 212, a gate terminal 214, and a body terminal 216. Body terminal 216 may be electrically connected to the body terminal 218 of the second transistor 204. Second transistor 204 may also have a source terminal 220, a drain terminal 222, and a gate terminal 224. Drain terminals 212 and 222 may be electrically coupled to one of the plurality of transistors 240 that comprise current source 206. Current source 206 may include a plurality of transistors, such as field effect transistors or transistors similar to those described in FIG. 1. The plurality of transistors 240 may be electrically connected in conventional ways and having a conventional structure as shown in FIG. 1. Source terminals 210 and 220 may be electrically connected to a first node 226. First node 226 may be electrically connected to one of a plurality of transistors 242 (FIG. 1) that are used to construct current sink 208. The plurality of transistors 242 may be conventional transistors, such as those shown in FIG. 1, and be electrically connected in conventional ways. A first differential input signal Vin1 is electrically connected to gate terminal 214. A second differential input signal Vin2 is electrically connected to gate terminal 224. Further features of each element in conventional comparator circuit structure 200 (e.g., function and material composition) are described in detail elsewhere herein relative to similar components in an FDSOI transistor 102 (FIG. 3) according to embodiments of the disclosure.

Turning to FIG. 3, a cross-sectional view of a type of fully depleted semiconductor on insulator (FDSOI) transistor 102 which may be deployed, e.g., in structures and methods according to the disclosure, is shown. FDSOI transistor 102 can be formed with structural features for reducing the electrical resistance across source and drain terminals S, D thereof. FDSOI transistor 102 and components thereof can be formed on and within a substrate 120. Substrate 120 can include any currently known or later-developed semiconductor material including, without limitation, one or more of the example semiconductor materials described elsewhere herein relative to substrate 20 (FIG. 1). A back-gate region 122, alternatively identified as an n-type or p-typed doped well region, of substrate 120 can be implanted or formed in-situ during deposition with one or more doping compounds to change the electrical properties thereof. Doping generally refers to a process by which foreign materials (“dopants”) are added to a semiconductor structure to alter its electrical properties, e.g., resistivity and/or conductivity. Where a particular type of doping (e.g., p-type or n-type) doping is discussed herein, it is understood that an opposite doping type may be implemented in alternative embodiments. Implantation refers to a process in which ions are accelerated toward a solid surface to penetrate the solid up to a predetermined range based on the energy of the implanted ions. Thus, back-gate region 122 can include the same material composition as the remainder of substrate 120, but can additionally include dopant materials therein. A buried insulator layer 124, also known in the art as a “buried oxide” or “BOX” layer, can separate back-gate region 122 of substrate 120 from source/drain regions 126 and a channel region 127 of FDSOI transistor 102. Buried insulator layer 124 therefore may be composed of one or more oxide compounds, and/or any other currently known or later-developed electrically insulative substances. The position of buried insulator layer 124 in a thin layer below the channel region 127 and extending below the source/drain regions 126 eliminates the need to add dopants to channel region 127. FDSOI transistor 102 therefore can be embodied as a “fully-depleted semiconductor on insulator” (FDSOI) structure, distinguishable from other structures (e.g., conventional transistor 12 (FIG. 1)) by including a dopant depleted channel region 127, buried insulator layer 124, back-gate nodes BG, etc., thereby allowing technical advantages such as an adjustable electric potential within back-gate region 122 of FDSOI transistor 102 as discussed elsewhere herein. Although FDSOI transistor 102 is shown and described as being formed with a particular arrangement of substrate 120, back-gate regions 122, and buried insulator layer 124, it is understood that FDSOI transistor 102 may alternatively be structured as a fin transistor, a nanosheet transistor, a vertical transistor, and/or one or more other currently-known or later-developed transistor structures for providing a back-gate terminal for adjusting the transistor's threshold voltage.

Source/drain regions 126 and channel region 127 may electrically couple a source terminal 128 of FDSOI transistor 102 to a drain terminal 130 of FDSOI transistor 102 when the transistor is in an on state. A gate stack 132 can be positioned over channel region 127, such that a voltage of gate node G controls the electrical conductivity between source and drain terminals 128, 130 through source/drain regions 126 and channel region 127. Gate stack 132 can have, e.g., one or more electrically conductive metals therein, in addition to a gate dielectric material (indicated with black shading between bottom of stack and channel region 127) for separating the conductive metal(s) of gate stack 132 from at least channel region 127. A group of trench isolations 134, in addition, can electrically and physically separate the various regions of FDSOI transistor 102 from parts of other transistors. Trench isolations 134 may be composed of any insulating material such as SiO₂ or a “high-k” dielectric having a high dielectric constant, which may be, for example, above 3.9. In some situations, trench isolations 134 may be composed of an oxide substance. Materials appropriate for the composition of trench isolations 134 may include, for example, silicon dioxide (SiO₂), hafnium oxide (HfO₂), alumina (Al₂O₃), yttrium oxide (Y₂O₃), tantalum oxide (Ta₂O₅), titanium dioxide (TiO₂), praseodymium oxide (Pr₂O₃), zirconium oxide (ZrO₂), erbium oxide (ErOₓ), and other currently known or later-developed materials having similar properties.

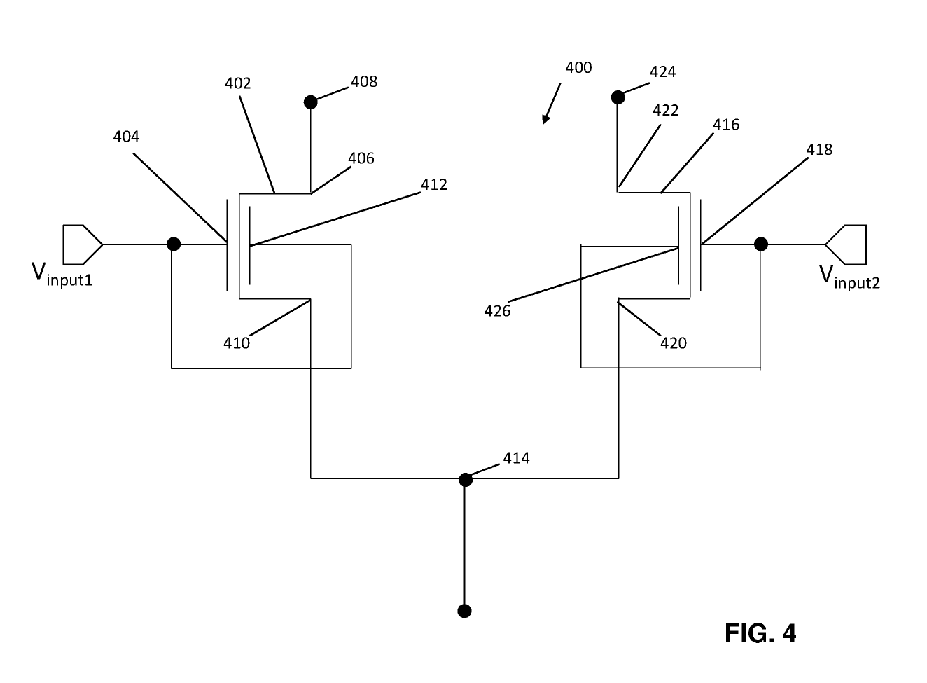

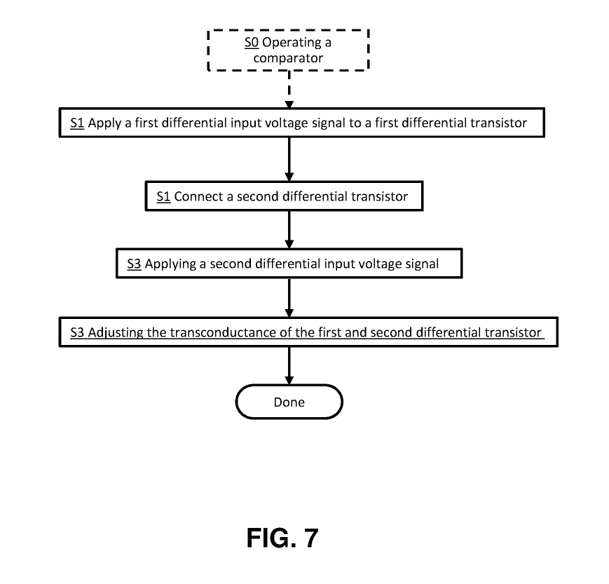

Back-gate region 122 can be electrically coupled to back-gate node BG through back-gate terminals 136 within substrate 120 to further influence the characteristics of 102, e.g., the conductivity between source and drain terminals 128, 130 through source/drain regions 126 and channel region 127. Applying an electrical potential to back-gate terminals 136 at back-gate node BG can induce an electric charge within back-gate region 122, thereby creating a difference in electrical potential between back-gate region 122 and source/drain regions 126, channel region 127, across buried insulator layer 124. Among other effects, this difference in electrical potential between elements, including back-gate region 122 and source/drain regions 126, channel region 127, and of substrate 120, can affect the threshold voltage of FDSOI transistor 102, i.e., the minimum voltage for inducing electrical conductivity across source/drain and channel regions 126, 127 between source and drain terminals 128, 130 as discussed herein. In particular, applying a back-gate biasing voltage to back-gate terminals 136 can lower the threshold voltage of FDSOI transistor 102, thereby reducing source drain resistance and increasing drain current, relative to the threshold voltage of FDSOI transistor 102 when an opposite voltage bias is applied to back-gate terminals 136. This ability of FDSOI transistor 102, among other things, can allow a reduced width (saving silicon area) relative to conventional applications and transistor structures. In an example embodiment, a width of source/drain and channel regions 126, 127 (i.e., into and out of the plane of the page) can be between approximately 0.3 micrometers (m) and approximately 2.4 μm. A length of source/drain and channel regions 126, 127 (i.e., left to right within the plane of the page) between first and second drain terminals 128, 130 can be, e.g., approximately twenty nanometers (nm). FDSOI technology transistors, e.g., FDSOI transistor 102, offer the ability to apply a voltage bias to back-gate region 122 to manipulate the threshold voltage Vₜ (i.e., minimum voltage for channel activation) of FDSOI transistor 102. As described herein, applying calibration voltages to back-gate region 122 can allow a user to reduce the local oscillator (LO) leakage and improve the linearity of an electronic transmitter. Back-gate region 122 can be coupled to an adjustable voltage to permit adjustment and calibration of the threshold voltage of FDSOI transistor 102. In circuit schematics shown in the accompanying FIGS. 4-5 and 7, any transistor which includes a back-gate terminal can be an embodiment of FDSOI transistor 102. Other transistors without back-gate terminals, by comparison, may alternatively take the form of any currently known or later developed transistor structure configured for use in a structure with FDSOI transistors 102.

FIG. 4 depicts an embodiment of differential pair 400 as part of a comparator circuit structure according to embodiments of the disclosure. Technical advantages and features described herein can be attainable by using embodiments of the FDSOI transistor 102 (FIG. 3) for each individual transistor element of differential pair circuit structure 400. Although FDSOI transistor 102 is shown in FIG. 3, it is understood that FDSOI transistor 102 may alternatively be structured as a fin transistor, a nanosheet transistor, a vertical transistor, and/or one or more other transistor described as being formed with a particular arrangement of a gate terminal, also referred to as a gate stack 132 in FIG. 3, and a back-gate terminal 136. The differential pair 400 of a comparator circuit may include a first transistor 402 having a gate terminal 404, a drain terminal 406 that may be electrically coupled to a first node 408, and a fully depleted semiconductor insulator (FDSOI) channel region. The FDSOI channel region may be positioned between a source terminal 410 and drain terminal 406, as demonstrated in FIG. 3. First transistor 402 may further include a back-gate terminal 412 separated from the FDSOI channel region by a buried insulator layer positioned beneath the FDSOI channel region. Back-gate terminal 412 of first transistor 402 and a first input signal voltage Vᵢₙₚᵤₜ₁ may be electrically connected to the gate terminal 404 of the first transistor 402. Source terminal 410 may then be electrically connected to a first shared node 414. Vᵢₙₚᵤₜ₁ may be coupled to a first signal voltage source (not shown) configured to transmit a differential signal.

Differential pair 400 may also include a second transistor 416 having a gate terminal 418, a source terminal 420, a drain terminal 422. As with the first transistor 402, a FDSOI channel region may be positioned between the source 420 and drain terminal 422, with a buried insulator positioned beneath the FDSOI channel region. As shown in FIG. 4 source terminal 420 may be electrically connected to first shared node 414 and drain terminal 422 may be electrically connected to second node 424. Back-gate terminal 426 of the second transistor 416 and a second input signal voltage Vᵢₙₚᵤₜ₂ may be electrically connected to the gate terminal 418 of the second transistor 416. Electrically connecting the back-gate terminal 426 to the gate terminal 418 allows the first transistor 402 and second transistor 416 to each act as greater than a single transistor, e.g., 1 and ⅕ transistor or 1 and ⅛ transistor, thereby increasing the transconductance of the device. When the first transistor 402 and second transistor 416 acting together, the two transistors comprise a differential pair 400. Second input signal voltage Vᵢₙₚᵤₜ₂ may be coupled to a first signal voltage source (not shown) and configured to transmit a differential signal.

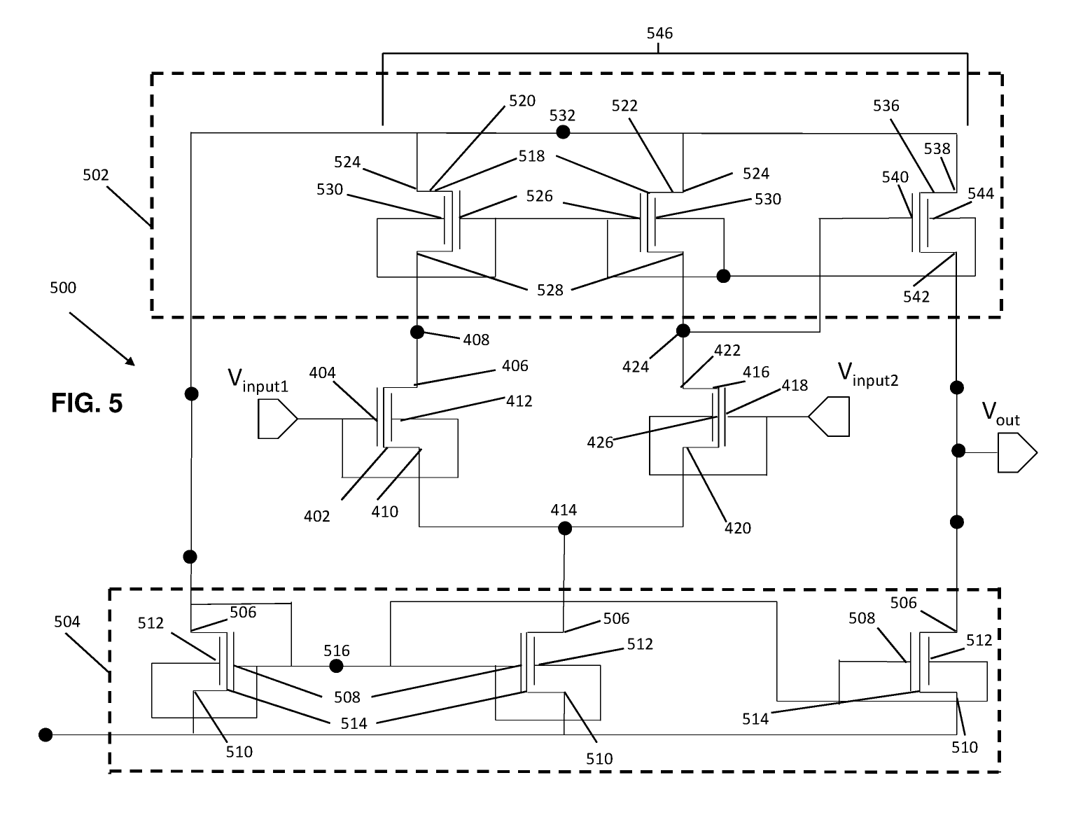

FIGS. 4 and 5 together provide an alternative embodiment of comparator circuit structure 500. A comparator circuit may have a current source load 502 that is electrically connected to first node 408 and second node 424. The current source load 502 may include a plurality of load current source transistors 546 that may be electrically connected to the first node 408 and second node 424 of the differential pair of transistors 402 and 416. Current source load 502 may be composed of conventional transistors, FDSOI transistors, or any other kind of transistor available. A comparator circuit may also have a current sink 504 electrically connected to first shared node 414. A current sink 504 could have a plurality of biasing current sink transistors 514 that are electrically connected to the first shared node 414 of the differential pair 402 and 416. Current sink 504 may also include conventional transistors, FDSOI transistors, or any other kind of transistor available.

Specifically, current sink 504 may include first shared node 414 electrically connected to a drain terminal 506 of one of a plurality of electrically connected transistors 514. Each transistor may have a gate terminal 508, a FDSOI channel region (as shown in FIG. 3) positioned between the drain terminal 506 and a source terminal 510, a back-gate terminal 512 that is separated from the FDSOI channel region with a buried insulator layer that is positioned beneath the FDSOI channel region (as shown in FIG. 3). The plurality of electrically connected transistors 514 may further include each of the back-gate terminals 512 of the plurality of transistors 514 being electrically connected at a second shared node 516. This electrical connection can reduce the need for additional circuit structures. The plurality of transistors 514 may also include each of the back-gate terminals 512 of the plurality of transistors 514 being electrically connected to each respective transistor gate terminal 508. Circuit structure 500 may allow for an increase in the transconductance of each of the plurality of electrically connected transistors 514.

Current source load 502 may also include a pair of load transistors 518. Pair of load transistors 518 may include a first load transistor 520 and a second load transistor 522, each load transistor having a source terminal 524, a gate terminal 526, a FDSOI channel region positioned between source terminal 524 and drain terminal 528, a back-gate terminal 530, separated from the FDSOI channel region with a buried insulator layer positioned beneath the FDSOI channel region (as shown in FIG. 3), wherein the drain 528 of the first load transistor 520 is electrically connected to the first node 408, and the drain 528 of the second load transistor 522 is electrically connected to the second node 424. Gate terminal 526 of the first load transistor 520 may be electrically connected to the gate terminal 526 of the second load transistor 522. Source terminals 524 of the load pair 518 may also be electrically connected to a third node 532. The current source load 502 of the comparator circuit structure 500 may also include electrically connected gate and back-gate terminals. Back-gate terminal 530 of first load transistor 520 may be electrically connected to the gate terminal 526 of the first load transistor 520. Back-gate terminal 530 of the second load transistor 522 may also be electrically connected to the gate terminal 526 of the second load transistor 522. This back-gate terminal 530 connection to the gate terminal 528 may allow for an increase in transconductance of each load transistor 520, 522 during operation.

Current source load 502 may also include a third transistor 536. Third transistor 536 may have a source terminal 538, a gate terminal 540 that can be electrically connected to the second node 424. Third transistor 536 may also be a conventional transistor or FDSOI transistor with a FDSOI channel region (as shown in FIG. 3) positioned between the source terminal 538 and a drain terminal 542, a back-gate terminal 544 separated from the FDSOI channel region with a buried insulator layer positioned beneath the FDSOI channel region (as shown in FIG. 3). Back-gate terminal 544 of the third transistor 536 may be electrically connected to the gate terminals 526 of the load pair of transistors 518. Source terminal 538 of the third transistor 536 is electrically connected to the third node 532.

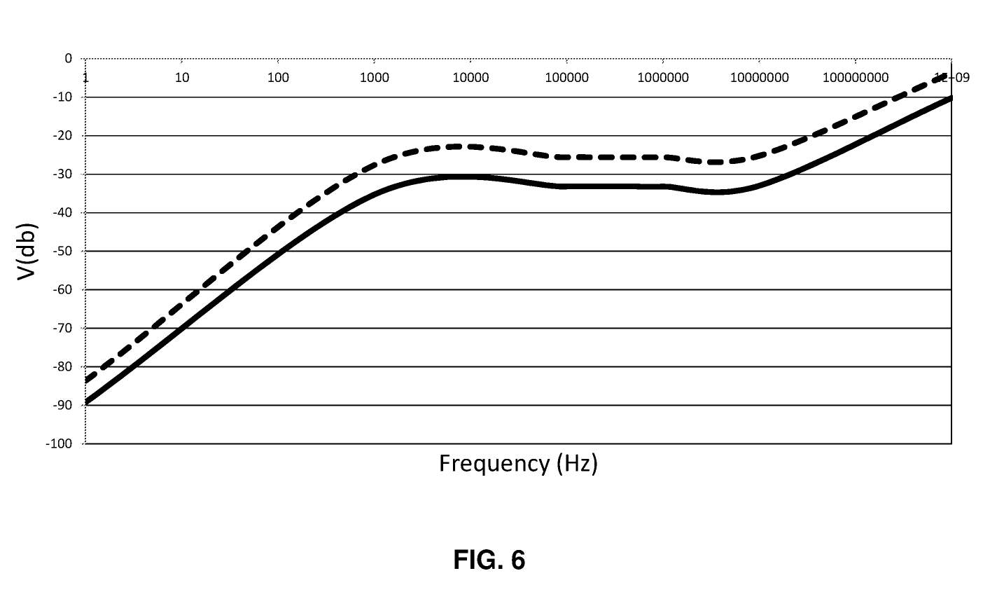

FIG. 6 shows a plot comparing voltage in decibels and frequency to show the difference in power supply rejection ratio (PSRR) of a conventional comparator circuit (FIG. 2), as indicated by the dashed line, and the comparator embodiments disclosed herein and shown in FIG. 5, as indicated by the solid line. The comparator circuit structure of FIG. 5 provides for approximately an 8 to 10-decibel improvement in PSRR. PSRR can be described as a measure of how much a circuit favors input signals over supply noise. By increasing the transconductance of a comparator circuit 500, input referred noise and random telegraph signal noise (RTS) are reduced. RTS is caused by carriers from the transistor channel being trapped and released in the silicon oxide layer of the transistor. This trapping and release phenomenon causes an undesirable shift in the threshold voltage of each device. Traditionally, comparators and other similar structures have required the use of additional circuit devices and bulky offset tracking circuitry to increase transconductance and/or reduce input referred noise and RTS noise. By coupling the gate terminals 402, 418 to the back-gate terminals 412, 426 of the first and second differential transistors 402, 416 allows each transistor to gain the strength greater than a single transistor, as the transistor takes into consideration the charge from both the gate terminal and back-gate terminal. This gain in transistor strength may equal 1 and ⅛, 1 and ⅕, or 1 and ⅓ transistors as determined by the process used and the relative thickness of the transistor gate oxide layer with respect to the thickness of the buried oxide layer. The gain in transistor strength correlates to an increase in the transconductance of each device. This same effect could not be repeated by using a conventional transistor as shown in FIG. 2, because coupling the body B of the conventional transistor 12 to gate G could result in undesirable forward biasing of the junction diodes. Conventional comparator structures, shown in FIG. 2, may be produced in bulk, but require the use of additional offset tracking circuitry. As a result of this additional circuitry, attempts to increase transconductance of the differential pair transistors, any higher than that obtained in a conventional structure (FIG. 2), may result in higher area consumption. The coupling of the gate terminals and back-gate terminals, as viewed in FIGS. 4 and 5 and described herein, using FDSOI transistors (FIG. 3) is effective at producing a stronger transistor device because of the inherent nature of the dual gate transistor e.g., gate terminal and back-gate terminal. The comparator structures disclosed herein and shown in FIGS. 4 and 5 may be used at higher back-gate voltages unlike in bulk technologies.

Additional improvements in PSRR may be obtained by electrically connecting the gates 526, 540 and back-gate terminals of the FDSOI transistors 520, 522, 536 found in current source load 502 and/or by electrically connecting the gates 508 to the back-gates of the FDSOI transistors located in the current sink 504. Such an improvement in PSRR may be exchanged for a reduction in area and/or power with appropriate scaling of device dimensions.

Referring to FIGS. 3-5 and 7 together, embodiments of the disclosure include methods for operating a comparator 500. Methods according to the disclosure can include applying a first differential input voltage signal Vᵢₙₚᵤₜ₁ to a gate terminal 404 of a first differential transistor 402. First differential transistor 402 may include a drain terminal 406 electrically coupled to a first node 408. A fully depleted semiconductor insulator (FDSOI) channel region, shown in FIG. 3, may be positioned between a source terminal 410 and the drain terminal 406. Back-gate terminal 412 can be separated from the FDSOI channel region with a buried insulator layer positioned beneath the FDSOI channel region (FIG. 3), wherein source terminal 410 may be electrically connected to first shared node 414.

Source terminal 420 of second differential transistor 416 may be electrically connected to first shared node 414. Second differential transistor 416 may include a gate terminal 418, a drain terminal 422 that could be electrically connected to a second node 424, a FDSOI channel region positioned between the source 420 and drain terminal 422, and a buried insulator positioned beneath the FDSOI channel region (FIG. 3) and a back-gate terminal 426;

A second differential input voltage signal Vᵢₙₚᵤₜ₂ may then be applied to the gate terminal 418 of the second differential transistor 416. The first and second differential input voltage signals may have a first level of Random Telegraph Signal (RTS) noise. The transconductance of the first transistor 402 and second differential transistor 416 may then be increased or adjusted by coupling the back-gate terminals 412, 426 of the first and second differential transistor 402, 416 to the respective gate terminals 404, 418 of the first and second differential transistors 402, 416. Adjusting the transconductance of the first and second differential transistor, 402 and 416, allows for a reduction in the level of RTS noise to a second level.

Biasing current sink 504 may include a plurality of transistors 514 that could be electrically connected to the first shared node 414 of the differential pair 402, 416. Current source load 502 may also include a plurality of transistors 546 that may be electrically connected to the first and second node 408, 424 of the differential pair 402, 416. The herein disclosed comparator structure may also be used to compare the first differential input voltage signal Vᵢₙₚᵤₜ₁ to the second differential input voltage signal Vᵢₙₚᵤₜ₂ and provide a digital signal output different than either the first and second differential input voltage signals Vᵢₙₚᵤₜ₁,Vᵢₙₚᵤₜ₂.

The flowcharts and block diagrams in the Figures illustrate the layout, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A comparator circuit structure comprising:
a first transistor having a gate terminal, a drain terminal electrically coupled to a first node, a fully depleted semiconductor on insulator (FDSOI) channel region positioned between a source terminal and the drain terminal, a back-gate terminal distinct from the gate terminal, separated from the FDSOI channel region with a buried insulator layer positioned beneath the FDSOI channel region, wherein the back-gate terminal of the first transistor and a first input signal voltage are electrically connected to the gate terminal of the first transistor, and the source terminal is electrically connected to a first shared node; and
a second transistor having a gate terminal, a source terminal electrically connected to the first shared node, a drain terminal electrically connected to a second node, a FDSOI channel region positioned between the source and drain terminal, and a buried insulator positioned beneath the FDSOI channel region and a back-gate terminal distinct from the gate terminal, wherein the back-gate terminal of the second transistor and a second input signal voltage are electrically connected to the gate terminal of the second transistor, and wherein the first and second transistor acting together comprise a differential pair.

2. The comparator circuit structure of claim 1, wherein the first input signal voltage is coupled to a first signal voltage source configured to transmit a differential signal.

3. The comparator circuit structure of claim 1, wherein the first shared node is electrically connected to a drain terminal of one of a plurality of electrically connected transistors, each transistor having a gate terminal, a FDSOI channel region positioned between the source terminal and a drain terminal, a back-gate terminal, separated from the FDSOI channel region with a buried insulator layer positioned beneath the FDSOI channel region, wherein a trench isolation forms an insulating barrier between the back-gate terminal and the gate terminal.

4. The comparator circuit structure of claim 3, wherein the plurality of electrically connected transistors further includes each of the back-gate terminals of the plurality of transistors being electrically connected at a second shared node.

5. The comparator circuit structure of claim 3, wherein the plurality of transistors further includes each of the back-gates of the plurality of transistors being electrically connected to each respective transistor gate terminal.

6. The comparator circuit structure of claim 1, further comprising a load pair of transistors including a first load transistor and a second load transistor, each load transistor having a source terminal, a gate terminal, a FDSOI channel region positioned between the source terminal and a drain terminal, a back-gate terminal, separated from the FDSOI channel region with a buried insulator layer positioned beneath the FDSOI channel region, wherein the drain of the first load transistor is electrically connected to the first node, and the drain of the second load transistor is electrically connected to the second node, and wherein the gate terminal of the first load transistor is electrically connected to the gate terminal of the second load transistor, and the source terminals of the load pair are electrically connected to a third node.

7. The comparator circuit structure of claim 6, wherein the back-gate terminal of the first load transistor is electrically connected to the gate terminal of the first load transistor, and the back-gate terminal of the second load transistor is electrically connected to the gate terminal of the second load transistor.

8. The comparator circuit structure of claim 6, further comprising a third transistor, having a source terminal, a gate terminal electrically connected to the second node, a FDSOI channel region positioned between the source terminal and a drain terminal, a back-gate terminal separated from the FDSOI channel region with a buried insulator layer positioned beneath the FDSOI channel region, wherein the back-gate terminal of the third transistor is electrically connected to the gate terminals of the load pair of transistors, and the source terminal of the third transistor is electrically connected to the third node.

9. A comparator circuit structure comprising:
a differential transistor pair including, a first transistor having a gate terminal, a drain terminal electrically connected to a first node, a fully depleted semiconductor on insulator (FDSOI) channel region positioned between a source terminal and the drain terminal, a back-gate terminal distinct from the gate terminal, separated from the FDSOI channel region with a buried insulator layer positioned beneath the FDSOI channel region, wherein the back-gate terminal of the first transistor and a first input signal voltage are electrically connected to the gate terminal of the first transistor, and the source terminal is electrically connected to a first shared node;
a second transistor having a gate terminal, a source terminal electrically connected to the first shared node, a drain terminal electrically connected to a second node, a FDSOI channel region positioned between the source and drain terminal, and a buried insulator positioned beneath the FDSOI channel region and a back-gate terminal distinct from the gate terminal, wherein the back-gate terminal of the second transistor and a second input signal voltage are electrically connected to the gate terminal of the second transistor;
a plurality of biasing current sink transistors electrically connected to the first shared node of the differential pair; and
a plurality of load current source transistors electrically connected to the first and second node of the differential pair.

10. The comparator circuit of claim 9, wherein one of the plurality of load current source transistors is electrically connected to the first node, and wherein one of the plurality of load current source transistors is electrically connected to the second node.

11. The comparator circuit of claim 9, wherein each of the plurality of biasing current sink transistors, further includes each transistor having a gate terminal, a FDSOI channel region positioned between a source terminal and a drain terminal, a back-gate terminal separated from the FDSOI channel region with a buried insulator layer positioned beneath the FDSOI channel region, wherein the drain of one of the plurality of transistors is electrically connected to the first shared node, wherein a trench isolation forms an insulating barrier between the back-gate terminal and the gate terminal.

12. The comparator circuit of claim 11, wherein the plurality of biasing current sink transistors further includes each of the back-gate terminals of the plurality of bias current sink transistors being electrically connected at a second shared node.

13. The comparator circuit of claim 11, wherein the plurality of biasing current sink transistors further includes each of the back-gates of the plurality of transistors being electrically connected to each respective transistor gate terminal.

14. The comparator circuit of claim 9, wherein the set of load current source transistors further comprises: a load pair of transistors including a first load transistor and a second load transistor, each having a source terminal, a gate terminal, a FDSOI channel region positioned between the source terminal and a drain terminal, a back-gate terminal, separated from the FDSOI channel region with a buried insulator layer positioned beneath the FDSOI channel region, wherein the drain of the first load transistor is electrically connected to the first node, and the drain of the second load transistor is electrically connected to the second node, and wherein the gate terminal of the first load transistor is electrically connected to the gate terminal of the second load transistor, and the source terminals of the load pair are electrically connected to a third node.

15. The comparator circuit of claim 14, wherein the back-gate terminal of the first load transistor is electrically connected to the gate terminal of the first load transistor, and the back-gate terminal of the second load transistor is electrically connected to the gate terminal of the second load transistor.

16. The comparator circuit of claim 14, further comprising a third transistor, having a source terminal, a gate terminal electrically connected to the second node, a FDSOI channel region positioned between the source terminal and a drain terminal, a back-gate terminal, separated from the FDSOI channel region with a buried insulator layer positioned beneath the FDSOI channel region, wherein the back-gate terminal of the third transistor is electrically connected to the gate terminals of the load pair of transistors, and the source terminal of the third transistor is electrically connected to the third node.

17. A method of operating a comparator, the method comprising:
applying a first differential input voltage signal to a gate terminal of a first differential transistor, wherein the first differential transistor includes a drain terminal electrically connected to a first node, a fully depleted semiconductor on insulator (FDSOI) channel region positioned between a source terminal and the drain terminal, and a back-gate terminal distinct from the gate terminal separated from the FDSOI channel region with a buried insulator layer positioned beneath the FDSOI channel region, wherein the source terminal is electrically connected to a first shared node;
connecting a source of a second differential transistor to the first shared node, wherein the second differential transistor including a gate, a drain terminal electrically connected to a second node, a FDSOI channel region positioned between the source and drain terminal, and a buried insulator positioned beneath the FDSOI channel region and a back-gate terminal distinct from the gate terminal, wherein a trench isolation forms an insulating barrier between the back-gate terminal and the gate terminal;
applying a second differential input voltage signal to the gate terminal of the second differential transistor, wherein the first and second differential input voltage signals have a first level of Random Telegraph Signal (RTS) noise; and
adjusting the transconductance of the first and second differential transistor by coupling the back-gate terminals of the first and second differential transistor to the respective gate terminals of the first and second differential transistors, wherein adjusting the transconductance reduces the RTS noise to a second level.

18. The method of claim 17, wherein a biasing current sink including a plurality of transistors is electrically a connected to the first shared node of the differential pair.

19. The method of claim 17, wherein a load current source including a plurality of transistors is electrically connected to the first and second node of the differential pair.

20. The method of claim 17, wherein the comparator compares the first differential input voltage signal to the second differential input voltage signal and outputs a digital signal different from the first and second differential input voltage signals.
